(19) United States
(12) Patent Application Publication
(10) Pub. No.: US 2026/0110589 A1
(43) Pub. Date: Apr. 23, 2026

(54) VACUUM LEAKAGE DETECTION DEVICE AND SEMICONDUCTOR MANUFACTURING SYSTEM COMPRISING THE SAME

(71) Applicant: Samsung Electronics Co., Ltd., Suwon-si (KR)

(72) Inventors: MIN-GU KANG, Seoul (KR); Moon Soo Bak, Seoul (KR); ChangWoo Son, Seoul (KR)

(73) Assignees: Samsung Electronics Co., Ltd., Suwon-si (KR); Research & Business Foundation SUNGKYUNKWAN UNIVERSITY, Suwon-si (KR)

(21) Appl. No.: 19/363,797

(22) Filed: Oct. 21, 2025

(30) Foreign Application Priority Data
Oct. 21, 2024 (KR) 10-2024-0144403
Dec. 18, 2024 (KR) 10-2024-0189601

(51) Int. Cl. G01M 3/20; G01M 3/26; H01L 21/67

(52) U.S. Cl. CPC G01M 3/20; G01M 3/26; H10P 72/0421

(57) ABSTRACT

A vacuum leakage detection device for detecting vacuum leakage from a semiconductor manufacturing device includes a first pipe to introduce a target chemical species from the semiconductor manufacturing device, an additional gas supplier configured to supply an additional chemical species through a second pipe to the first pipe to react with the target chemical species, a flow meter configured to control a flow rate of the additional chemical species, a plasma generator connected to the first pipe and configured to convert a monitoring chemical species into a plasma state, the monitoring chemical species being generated by reaction of the target chemical species and the additional chemical species, a sensor configured to obtain emission spectrum data for the monitoring chemical species from the plasma generator, and a processor configured to calculate a leakage amount of the target chemical species, based on emission intensity of the monitoring chemical species.

### CROSS-REFERENCE TO RELATED APPLICATIONS

This application claims priority under 35 U.S.C. § 119 to Korean Patent Application Nos. 10-2024-0144403 and 10-2024-0189601 filed on Oct. 21, 2024 and Dec. 18, 2024, respectively, in the Korean Intellectual Property Office, the disclosures of which are incorporated by reference herein in their entireties.

### BACKGROUND

Embodiments of the present disclosure described herein relate to a vacuum leakage detection device and a semiconductor manufacturing system including the same.

In general, a series of processes such as deposition, etching, and cleaning are performed to manufacture a semiconductor device. The manufacturing processes of the semiconductor device are performed in a process chamber to prevent contamination of a wafer. If leakage from the process chamber occurs so that an external gas is introduced into the process chamber, the corresponding gas reacts with the wafer, and therefore the wafer has a defect. Accordingly, a technology for detecting occurrence or non-occurrence of leakage from the process chamber is advantageous.

### SUMMARY

Embodiments of the present disclosure provide a detection device for efficiently detecting vacuum leakage from a process chamber, a semiconductor manufacturing system including the detection device, and a method for operating a vacuum leakage detection device.

Provided is a vacuum leakage detection device for detecting vacuum leakage from a process chamber or semiconductor manufacturing device, the vacuum leakage detection device including: a first pipe to introduce a target chemical species from the process chamber or semiconductor manufacturing device, the first pipe being configured to be connected with the semiconductor manufacturing device; an additional gas supplier configured to supply an additional gas including an additional chemical species to the first pipe to react with the target chemical species; a second pipe connecting the additional gas supplier and the first pipe to introduce the additional chemical species to the first pipe; a flow meter disposed in-line with the second pipe and configured to control a flow rate of the additional chemical species into the first pipe; a plasma generator connected to the first pipe and configured to convert a monitoring chemical species into a plasma state, the monitoring chemical species being generated by reaction of the target chemical species and the additional chemical species; a sensor configured to obtain emission spectrum data for the monitoring chemical species from the plasma generator; and a processor configured to calculate a leakage amount of the target chemical species from the process chamber or semiconductor manufacturing device, based on emission intensity as determined from the emission spectrum data of the monitoring chemical species.

Also provided is a semiconductor manufacturing system including: a process chamber or a semiconductor manufacturing device; and a vacuum leakage detection device connected to the process chamber or semiconductor manufacturing device and configured to detect vacuum leakage from the process chamber or semiconductor manufacturing device, in which the vacuum leakage detection device includes: a first pipe to introduce a target chemical species from the process chamber or semiconductor manufacturing device, the first pipe being configured to be connected with the process chamber or semiconductor manufacturing device; an additional gas supplier configured to supply an additional gas including an additional chemical species to the first pipe to react with the target chemical species; a second pipe connecting the additional gas supplier and the first pipe to introduce the additional chemical species to the first pipe; a flow meter disposed in-line with the second pipe and configured to control a flow rate of the additional chemical species into the first pipe; a plasma generator connected to the first pipe and configured to convert a monitoring chemical species into a plasma state, the monitoring chemical species being generated by reaction of the target chemical species and the additional chemical species; a sensor configured to obtain emission spectrum data for the monitoring chemical species from the plasma generator; and a processor configured to calculate a leakage amount of the target chemical species from the process chamber or semiconductor manufacturing device, based on emission intensity as determined from the emission spectrum data of the monitoring chemical species.

Further provided is a method for operating a vacuum leakage detection device, the method including: providing a target chemical species through a first pipe to a plasma generator; setting an initial concentration of an additional chemical species to react with the target chemical species; controlling a flow meter disposed in-line with a second pipe through which the additional chemical species is to be transmitted, based on the initial concentration of the additional chemical species; generating a monitoring chemical species by reacting the target chemical species and the additional chemical species; exciting the monitoring chemical species into a plasma state within the plasma generator by activating the plasma generator; and obtaining emission spectrum data for the monitoring chemical species from the plasma generator.

### BRIEF DESCRIPTION OF THE FIGURES

The above and other objects and features of the present disclosure will become apparent by describing in detail embodiments thereof with reference to the accompanying drawings.

FIG. 1 is a view illustrating a semiconductor manufacturing system according to an embodiment of the present disclosure.

FIG. 2 is a flowchart for explaining operation of a vacuum leakage detection device of FIG. 1.

FIG. 3 is a view illustrating an example of an experimental result showing a correlation between the emission intensity of a target chemical species and the emission intensity of a monitoring chemical species according to an embodiment of the present disclosure.

FIGS. 4A to 4F are views illustrating examples of experimental results on the emission intensity of the target chemical species or the monitoring chemical species depending on a change in the flow rate of the target chemical species under different vacuum pressure conditions.

FIG. 5 is a view illustrating a semiconductor manufacturing system according to an embodiment of the present disclosure.

FIG. 6 is a view illustrating a semiconductor manufacturing system according to an embodiment of the present disclosure.

FIG. 7 is a view illustrating a semiconductor manufacturing system according to an embodiment of the present disclosure.

FIG. 8 is a flowchart for explaining an example of operation of the semiconductor manufacturing system and a vacuum leakage detection device of FIG. 7.

FIG. 9 is a view illustrating a semiconductor manufacturing system according to an embodiment of the present disclosure.

FIG. 10 is a flowchart for explaining an example of operation of the semiconductor manufacturing system and a vacuum leakage detection device of FIG. 9.

### DETAILED DESCRIPTION

Hereinafter, embodiments of the present disclosure will be described clearly and in detail to such an extent that those skilled in the art may easily implement the present disclosure.

Hereinafter, embodiments will be described with reference to the accompanying drawings. Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “comprising” or “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Terms such as the “same” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

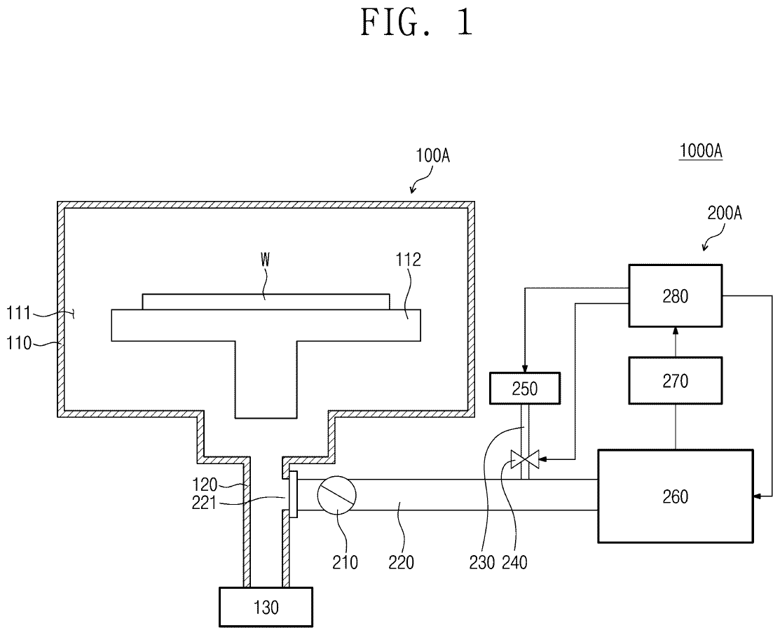

FIG. 1 is a view illustrating a semiconductor manufacturing system according to an embodiment of the present disclosure.

The semiconductor manufacturing system 1000A according to an embodiment of the present disclosure may include a vacuum leakage detection device 200A for detecting vacuum leakage from a process chamber. Here, the vacuum leakage may refer to an occurrence in which the vacuum level of the process chamber is not maintained and an external gas is introduced into the process chamber.

In order to efficiently detect the vacuum leakage, the vacuum leakage detection device 200A may add an additional chemical species to a target chemical species. Here, the target chemical species may be a chemical species to be detected to determine occurrence or non-occurrence of the vacuum leakage and may be one of the components of the atmosphere. In this example, the target chemical species reacts with the additional chemical species, and a new chemical species may be generated. The new chemical species has a linear correlation with the target chemical species and may have higher emission intensity than the target chemical species.

The vacuum leakage detection device 200A may monitor the new chemical species instead of the target chemical species and may obtain emission spectrum data for the new chemical species. The vacuum leakage detection device 200A may calculate occurrence or non-occurrence of vacuum leakage of the target chemical species and the amount of the target chemical species that has leaked, based on the emission intensity from the emission spectrum data for the new chemical species. As a result, even when a very small amount of external gas is introduced into the process chamber and the concentration of the target chemical species is extremely low, the vacuum leakage detection device 200A may efficiently detect vacuum leakage by monitoring the new chemical species with high sensitivity.

In more detail, referring to FIG. 1, the semiconductor manufacturing system 1000A may include a semiconductor manufacturing device 100A and the vacuum leakage detection device 200A.

The semiconductor manufacturing device 100A may include a process chamber 110 and a vacuum pump 130.

As used herein, a semiconductor manufacturing device 100A may refer to any device used in a process of manufacturing a semiconductor device. A semiconductor device may refer, for example, to a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices. Semiconductor packages may include a package substrate, one or more semiconductor chips, and an encapsulant formed on the package substrate and covering the semiconductor chips.

Non-limiting examples of a semiconductor manufacturing device may include for example, a device used in wafer production, photoresist coating, photolithography, etching, deposition, doping, ion implantation, metallization, wafer testing and packaging. Non-limiting example devices may include an enclosed, controlled environment, such as a vacuum chamber, or other process chamber where processing steps such as chemical vapor deposition (CVD), physical vapor deposition (PVD), plasma etching, or ion implantation may be performed, e.g. on silicon wafers to create microchips, or a process chamber for a cleaning process. Example vacuum pumps that may be semiconductor manufacturing devices may include for example dry vacuum pumps and turbo-molecular pumps that may be used for example in etching or deposition processes.

The process chamber 110 may provide a sealed space 111 for performing a deposition process, an etching process, and a cleaning process on a wafer W. For example, the process chamber 110 may include or be a metal such as aluminum or stainless steel. When the deposition process, the etching process, and the cleaning process are performed, the introduction of an external gas into the process chamber 110 may be blocked, and the process chamber 110 may be maintained in a vacuum state.

A wafer stage 112 for supporting the wafer W may be disposed in the process chamber 110. For example, the wafer stage 112 may serve as a susceptor for supporting the wafer W. In an embodiment, the wafer stage 112 may include, at the top thereof, an electrostatic chuck for holding the wafer W with an electrostatic attractive force.

A gate (not illustrated) through which the wafer W enters and exits the process chamber 110 may be installed in a sidewall of the process chamber 110. Through the gate, the wafer W may be loaded on the wafer stage 112 or may be unloaded from the wafer stage 112.

The vacuum pump 130 may be connected to the process chamber 110 through an exhaust pipe 120. The vacuum pump 130 may adjust the pressure in the inner space 111 of the process chamber 110 to a desired level of vacuum pressure. In addition, the vacuum pump 130 may discharge process by-products and residual process gases generated in the process chamber 110 to the outside. The vacuum pump 130 may be, for example, a turbo molecular pump or a dry pump. However, this is illustrative, and the present disclosure is not limited thereto.

The vacuum leakage detection device 200A may detect occurrence or non-occurrence of vacuum leakage from the process chamber 110 and may calculate the amount of leakage. To achieve this, the vacuum leakage detection device 200A may include an isolation valve 210, a first pipe 220, a second pipe 230, a flow meter 240, an additional gas supplier 250, a plasma generator 260, a monitoring device or sensor 270, and a processor 280.

The processor 280 may include or be one or multiple processors or computers and may be for example a microprocessor, a CPU (Central Processing Unit), a GPU (graphics processor), a digital signal processor (DSP), a field-programmable gate array (FPGA), etc., and may be part of a computer or interconnected computers. The processor may be configured by software.

The isolation valve 210 may connect the vacuum leakage detection device 200A to the semiconductor manufacturing device 100A or may isolate the vacuum leakage detection device 200A from the semiconductor manufacturing device 100A. For example, the vacuum leakage detection device 200A may be implemented as a small movable device, and the isolation valve 210 may attach/detach the vacuum leakage detection device 200A to/from the semiconductor manufacturing device 100A.

For example, as illustrated in FIG. 1, the exhaust pipe 120 may be disposed at the bottom of the process chamber 110, and a sampling inlet 221 may be provided in one side surface of the exhaust pipe 120. In this example, the isolation valve 210 may correspond to the sampling inlet 221 and may attach/detach the vacuum leakage detection device 200A to/from the sampling inlet 221 with the process chamber 110 maintained in the vacuum state. For example, the isolation valve 210 may be a manual valve. However, this is illustrative, and the present disclosure is not limited thereto.

The first pipe 220 may be connected between the exhaust pipe 120 and the plasma generator 260, such as a self-plasma generator. Through the first pipe 220, a process gas in the process chamber 110 and/or a gaseous by-product after reaction may be provided from the process chamber 110 to the plasma generator 260.

If vacuum leakage occurs, a very small amount of outside air may be introduced into the process chamber 110. In this example, a very small amount of atmospheric components introduced into the process chamber 110 may also be provided to the plasma generator 260 through the first pipe 220 together with the process gas and/or the gaseous by-product.

In an embodiment, in order to prevent the process gas and/or the gaseous by-product from be deposited in the first pipe 220, a first heating jacket (not illustrated) may be disposed to surround the first pipe 220. The first heating jacket may apply heat to the first pipe 220 to prevent the process gas and/or the gaseous by-product from being deposited in the first pipe 220. In example embodiments a connector may be present at one or both ends of the first pipe 220. For example there may be a connector to connect the first pipe 220 to the process chamber 110 or exhaust pipe 120 or other component of the semiconductor manufacturing device 100A. There may also (or alternatively) be a connector connecting the first pipe 220 to the plasma generator 260.

The second pipe 230 may be connected between the additional gas supplier 250 and the first pipe 220. An additional gas generated from the additional gas supplier 250 may be provided to the first pipe 220 through the second pipe 230. In an embodiment, in order to prevent the additional gas from being deposited in the second pipe 230, a second heating jacket (not illustrated) may be disposed to surround the second pipe 230. In example embodiments a connector may be present at one or both ends of the second pipe 230. For example there may be a connector to connect the second pipe 230 to the first pipe 220. There may also (or alternatively) be a connector connecting the second pipe 230 to the gas supplier 250.

The additional gas supplier 250 may provide the additional gas to the first pipe 220 through the second pipe 230. The additional gas provided through the additional gas supplier 250 may be supplied to the plasma generator 260 together with the process gas and/or the gas mixture in the first pipe 220. Here, the additional gas may be a gas containing an additional chemical species, and the additional chemical species may refer to a chemical species capable of generating a new chemical species with high emission intensity by reacting with a target chemical species to be detected.

The flow meter 240 may be disposed in-line with the second pipe 230. The flow meter 240 may control the flow rate in the second pipe 230 such that the additional gas generated from the additional gas supplier 250 is provided to the first pipe 220, for example by a predetermined or desired amount. For example, the flow meter 240 may be a needle valve. However, this is illustrative, and the present disclosure is not limited thereto.

The plasma generator 260 may generate high-density plasma. The plasma generated from the plasma generator 260 may excite or convert an inert gas introduced through the first pipe 220 and the second pipe 230 into a plasma state. At this time, light may be generated from the plasma generator 260.

In an embodiment of the present disclosure, the target chemical species and the additional chemical species may be introduced into the plasma generator 260 through the first pipe 220 and the second pipe 230, and the target chemical species and the additional chemical species may react to generate a new chemical species with high emission intensity. Thereafter, the plasma generator 260 may excite the new chemical species into plasma, and thus light corresponding to the new chemical species may be generated.

In this example, the new chemical species may not only have higher emission intensity than the target chemical species to be measured, but may also have a correlation with the target chemical species. For example, the emission intensity of the new chemical species may linearly increase as the concentration of the target chemical species increases.

In an embodiment, the target chemical species to be detected to detect occurrence or non-occurrence of vacuum leakage may be one of the components of the external atmosphere. For example, the target chemical species may be nitrogen (N). In this example, the additional chemical species may be carbon (C), and the additional gas may be carbon dioxide (CO₂) containing carbon (C). In this example, the new chemical species may be a cyano radical (hereinafter referred to as (“CN”)). However, this is illustrative, and the present disclosure is not limited thereto. For example, in some embodiments, the new chemical species may be a carbon nitride, such as cyanogen. For example, in some embodiments, the target chemical species may be one of hydrogen (H), nitrogen (N), and oxygen (O), and the additional gas may be methane gas (CH₄). In this example, the new chemical species may be one of a hydrocarbon (“CH”), a cyano radical (“CN”), and an oxocarbon (“CO”). As used herein “CO” refers to an oxocarbon generally and not carbon monoxide specifically. Hereinafter, for convenience of description, it is assumed that the target chemical species is “N”, the additional chemical species is “C”, and the new chemical species is “CN”, however these embodiments are not intended to be limiting. In an embodiment, the plasma generator 260 may be for example, a self-plasma generator 260 and may generate plasma through a self-plasma generator method or other plasma generating method. For example, an inductively coupled plasma (ICP) method may be used to generate plasma. In this example, the plasma generator 260 may be implemented in a relatively small size. For example, ICP-Optical Emission Spectroscopy (ICP-OES) devices and methods may be used. ICP-OES includes for example, generating an aerosol that is sprayed into an ICP torch containing an argon gas plasma, which is a highly energetic, ionized gas. The plasma may be generated by an RF induction coil that creates a high-frequency magnetic field, exciting the argon gas. The extreme heat of the plasma vaporizes the aerosol droplets, then breaks them down into individual atoms (atomization), and excites the electrons in those atoms to higher energy levels. As the excited electrons return to their original, lower energy levels, they emit photons (light) at specific wavelengths unique to each element. The emitted light is passed through a prism, which separates the different wavelengths into a spectrum. A detector system 270, such as a Charge-Coupled Device (CCD) or Charge-Injection Device (CID) solid-state detectors, may be used to measure the intensity of the light at specific wavelengths, allowing one to identify and quantify the elements present in the original sample.

This is illustrative, and in some embodiments, the plasma generator 260 may generate plasma through e.g., a capacitively coupled plasma (CCP) method or a microwave method. A plasma CCP (Capacitively Coupled Plasma) method generates plasma by applying radio frequency (RF) power to one electrode in a vacuum chamber containing gas, creating a time-varying electric field between it and a grounded electrode. This process creates a low-density, high-ion-energy plasma that is useful for etching materials, with the energy of the ions controlled by the bias voltage on the powered electrode.

The monitoring device or sensor 270 (e.g., a light sensor, such as a spectrometer or a photodetector) may obtain emission spectrum data for the new chemical species. For example, the monitoring device or sensor 270 may monitor the new chemical species (e.g., “CN”) having a strong correlation with the target chemical species (e.g., “N”) in real time and may obtain the emission spectrum for the new chemical species. The the new chemical species “CN” may have a higher emission intensity than the target chemical species and may have a correlation with the target chemical species, and is referred to as a “monitoring chemical species”. Because the monitoring chemical species has higher emission intensity than that the target chemical species, even when the target chemical species is introduced in a very small amount, a change in the emission spectrum for the monitoring chemical species obtained by the monitoring device or sensor 270 may be sufficiently large to detect vacuum leakage and calculate the amount of leakage. In non-limiting example embodiments, the target chemical species is nitrogen N₂, the additional chemical species is carbon dioxide CO₂, and the monitoring chemical species is cyanogen (CN)₂.

A self-plasma optical emission spectroscopy (SPOES) sensor may be an example of the plasma generator 260 a monitoring device or sensor 270 (e.g., spectrometer). Self-plasma optical emission spectroscopy (SPOES) includes semiconductor process monitoring and leak detection devices and techniques that use a localized, in-situ micro-plasma to analyze residual gases in an exhaust or process line. The SPOES process works by detecting specific wavelengths of light emitted by excited species in the self-generated plasma, which are unique to different gases. This provides real-time, non-intrusive, and flexible analysis capabilities for process monitoring, end-point detection, and leak detection in complex manufacturing tools. A compact, localized micro-plasma is generated within the SPOES sensor itself, e.g. within the plasma generator 260. This self-plasma excites the gas molecules. A high-resolution spectrometer in the SPOES system (which is a monitoring device or sensor 270) captures this emitted light across a wide spectral range. By analyzing the unique spectral lines, e.g. by a processor 280, the SPOES can identify the composition of the gases of the monitoring chemical species for example, and determine if unexpected species (like air during a leak) are present.

The processor 280 may obtain emission spectrum data for the monitoring chemical species from the monitoring device 270. The processor 280 may detect occurrence or non-occurrence of vacuum leakage based on the emission spectrum data for the monitoring chemical species. In addition, the processor 280 may calculate the amount of the target chemical species that has leaked, based on the emission spectrum data for the monitoring chemical species.

In an embodiment, the processor 280 may calculate the leakage amount of the target chemical species corresponding to the emission intensity of the monitoring chemical species, based on a correlation (e.g., a previously determined correlation) between the emission intensity of the monitoring chemical species and the leakage amount of the target chemical species. For example, the emission intensity of the monitoring chemical species may linearly increase in proportion to the concentration of the target chemical species. In this example, the processor 280 may quantitatively obtain the leakage amount of the target chemical species from the emission intensity of the monitoring chemical species.

In an embodiment, depending on the pressure at which the process is performed and the concentration of the added additional chemical species, the correlation between the emission intensity of the monitoring chemical species and the leakage amount of the target chemical species may be derived from different correlation equations. In some embodiments, the processor 280 may support machine learning, and the correlation equations may be derived through a model obtained through the machine learning.

The processor 280 may control overall operation of the vacuum leakage detection device 200A. For example, the processor 280 may control the concentration of the additional gas by controlling the flow meter 240. For example, the processor 280 may adjust the concentration of the additional gas by controlling the flow meter 240 such that a change in the monitoring chemical species is efficiently detected.

In addition, the processor 280 may be implemented to control overall operation of the additional gas supplier 250, the plasma generator 260, and the monitoring device 270.

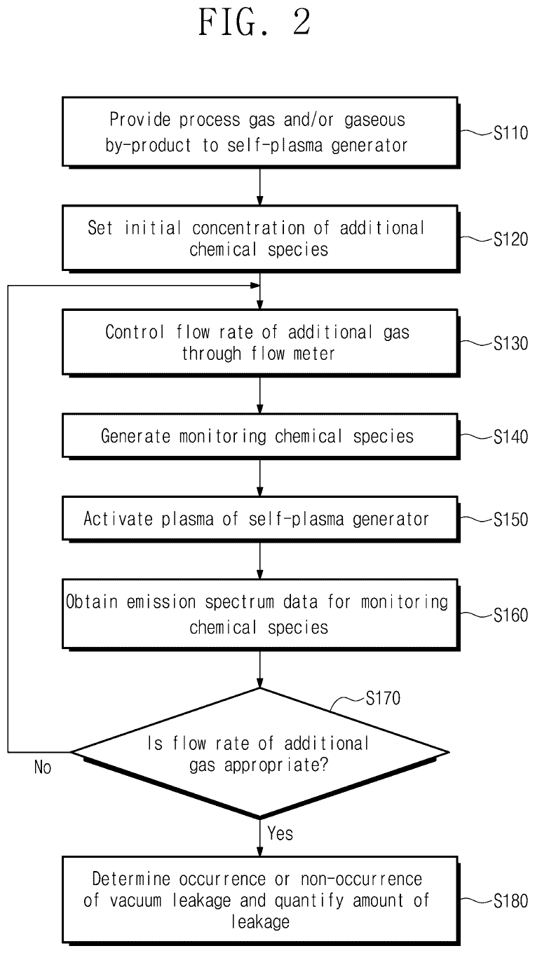

FIG. 2 is a flowchart for explaining operation of the vacuum leakage detection device 200A of FIG. 1.

In step S110, the process gas and/or the gaseous by-product may be provided to the plasma generator 260.

For example, the process gas and/or the gaseous by-product may be provided to the plasma generator 260 through the first pipe 220 connected to the exhaust pipe 120 of the semiconductor manufacturing device 100A. If vacuum leakage occurs, nitrogen (N) that is a component of the atmosphere introduced from the outside may be introduced into the plasma generator 260 together.

In step S120, the initial concentration of the additional chemical species may be set.

For example, when the target chemical species is “N”, the additional chemical species is “C”, and the monitoring chemical species is “CN”, the processor 280 may set the initial concentration of the additional chemical species “C”.

In step S130, the processor 280 may control the flow rate of the additional gas through the flow meter 240.

For example, the processor 280 may control the flow rate of carbon dioxide provided through the flow meter 240, based on the initial set concentration of the additional chemical species “C”. Accordingly, the additional gas corresponding to the set flow rate may be provided to the plasma generator 260.

In step S140, the monitoring chemical species may be generated.

For example, the target chemical species “N” and the additional chemical species “C” introduced into the plasma generator 260 (such as a self-plasma generator 260) may react with each other to generate the monitoring chemical species, such as “CN”. The monitoring chemical species “CN” may have higher emission intensity than the target chemical species “N” while being correlated with the target chemical species “N”. The monitoring chemical species, such as “CN”, may be created within the plasma generator 260. In non-limiting examples, the new chemical species and/or monitoring chemical species may be at least partially generated within the first pipe after introduction of the target chemical species and the additional chemical species to the first pipe.

In step S150, the plasma of the plasma generator 260 may be activated.

For example, the plasma of the plasma generator 260 may be activated, and thus the monitoring chemical species “CN” may be excited or converted into a plasma state. In this process, light corresponding to the monitoring chemical species “CN” may be emitted.

In step S160, the emission spectrum data for the monitoring chemical species may be obtained.

For example, the monitoring device 270 may be a sensor such as a spectrometer that obtains the emission spectrum data for the monitoring chemical species “CN” generated in the plasma process.

In step S170, it may be determined whether the flow rate of the additional gas is appropriate.

For example, the processor 280 may determine whether the concentration of the additional chemical species “C” added through the second pipe 230 is appropriate, based on the emission spectrum data of the monitoring chemical species “CN”.

The appropriate concentration of the additional chemical species “C” may vary depending on the concentration of the target chemical species, the pressure level in the vacuum state, and/or the emission intensity of the monitoring chemical species. For example, the processor 280 may estimate the concentration of the target chemical species from the pressure level of the vacuum state of the process chamber 110 and the emission spectrum data of the additional chemical species and may estimate the appropriate concentration of the additional chemical species based on the estimated concentration of the target chemical species. Thereafter, the processor 280 may determine whether the flow rate of the added additional gas is appropriate.

If the flow rate of the additional gas is not appropriate or suitable, step S130 may be performed again. For example, the processor 280 may adjust the flow rate of the additional gas to an appropriate level by controlling the flow meter 240. Accordingly, more clear emission spectrum data for the monitoring chemical species may be obtained.

If the flow rate of the additional gas is appropriate, step S180 may be performed.

In step S180, the processor 280 may determine occurrence or non-occurrence of vacuum leakage and may quantify the amount of leakage.

For example, the processor 280 may determine occurrence or non-occurrence of vacuum leakage based on the emission spectrum data for the monitoring chemical species “CN”. Thereafter, the processor 280 may quantify the amount of leakage based on the correlation between the monitoring chemical species “CN” and the target chemical species “N”.

As described with reference to FIGS. 1 and 2, the vacuum leakage detection device 200A according to an embodiment of the present disclosure may generate the monitoring chemical species having a strong correlation with the target chemical species while having higher emission intensity than the target chemical species and may obtain the emission spectrum data for the monitoring chemical species. The vacuum leakage detection device 200A may calculate occurrence or non-occurrence of vacuum leakage and the amount of leakage, based on the emission spectrum data for the monitoring chemical species. As a result, even when a very small amount of external gas is introduced into the process chamber and the concentration of the target chemical species is extremely low, the vacuum leakage detection device 200A may efficiently detect vacuum leakage.

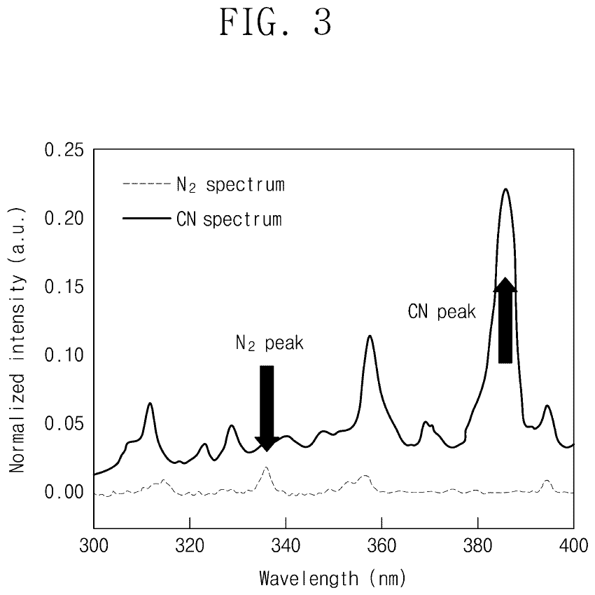

FIG. 3 is a view illustrating an example of an experimental result showing a correlation between the emission intensity of the target chemical species and the emission intensity of the monitoring chemical species according to an embodiment of the present disclosure. In FIG. 3, an experimental result when the target chemical species is “N₂” and the monitoring chemical species is cyano radical “CN” is illustrated as an example.

Referring to FIG. 3, the emission intensity depending on the wavelength of the target chemical species “N₂” was first measured. Thereafter, the monitoring chemical species “CN” was generated by adding a small amount of carbon dioxide as an additional gas in the state in which the flow rate of the target chemical species “N₂” was the same.

It can be confirmed that, as illustrated in FIG. 3, the emission intensity of the monitoring chemical species “CN” is higher than the emission intensity of the target chemical species “N₂” in the state in which the flow rate of “N₂” is the same.

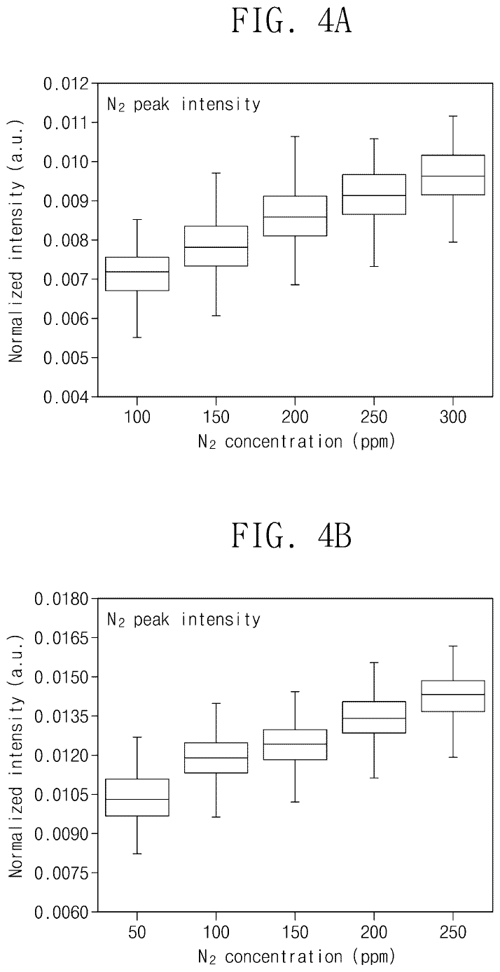

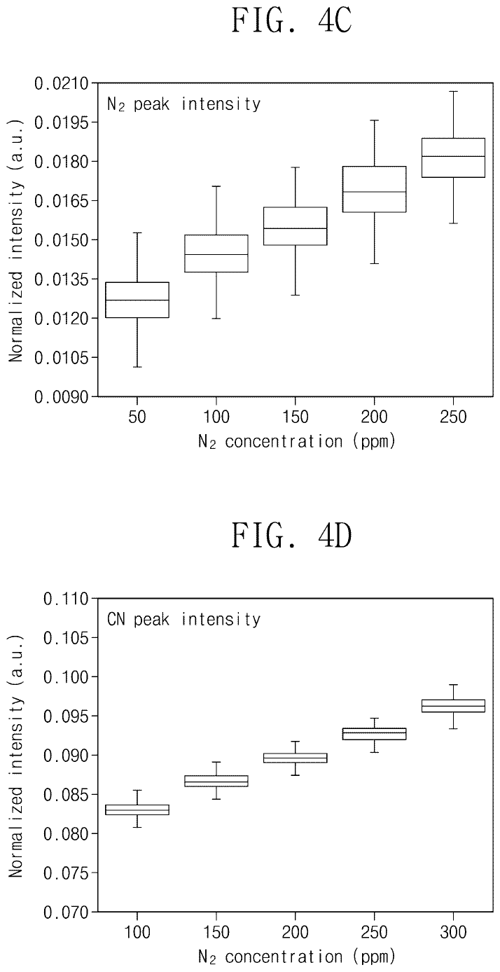

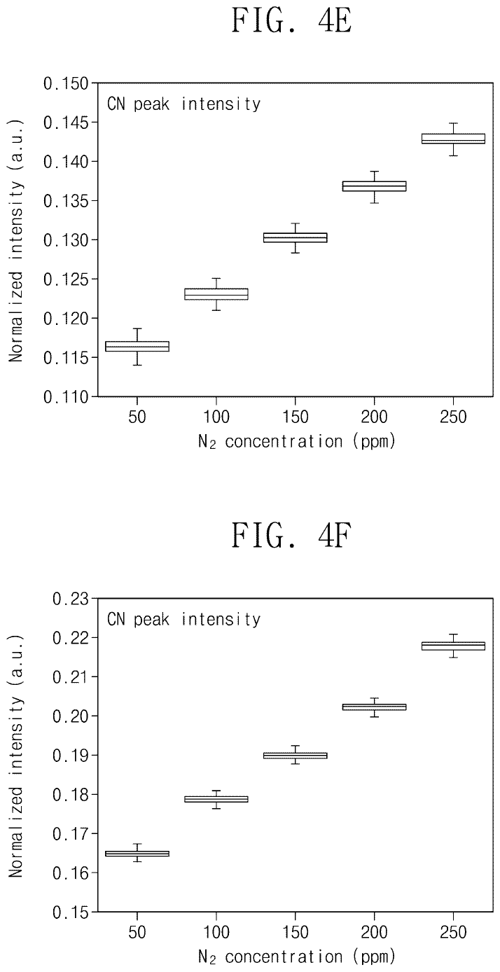

FIGS. 4A to 4F are views illustrating examples of experimental results on the emission intensity of the target chemical species or the monitoring chemical species depending on a change in the flow rate of the target chemical species under different vacuum pressure conditions.

Specifically, FIG. 4A illustrates the emission intensity of the target chemical species “N₂” when the pressure in the vacuum state is 100 mTorr and carbon dioxide that is an additional gas is not added. FIG. 4B illustrates the emission intensity of the target chemical species “N₂” when the pressure in the vacuum state is 150 mTorr and carbon dioxide that is an additional gas is not added. FIG. 4C illustrates the emission intensity of the target chemical species “N₂” when the pressure in the vacuum state is 200 mTorr and carbon dioxide that is an additional gas is not added. FIG. 4D illustrates the emission intensity of the monitoring chemical species “CN” when the pressure in the vacuum state is 100 mTorr and carbon dioxide that is an additional gas is added. FIG. 4E illustrates the emission intensity of the monitoring chemical species “CN” when the pressure in the vacuum state is 150 mTorr and carbon dioxide that is an additional gas is added. FIG. 4F illustrates the emission intensity of the monitoring chemical species “CN” when the pressure in the vacuum state is 200 mTorr and carbon dioxide that is an additional gas is added.

First, referring to FIGS. 4A to 4C, it can be confirmed that, in the state in which the additional gas is not added, the emission intensity of the target chemical species “N₂” is not significantly changed even though the concentration of the target chemical species “N₂” is increased in units of 50 PPM.

In contrast, referring to FIGS. 4D to 4F, it can be confirmed that, in the state in which carbon dioxide that is an additional gas is added, the emission intensity of the monitoring chemical species “CN” is significantly changed when the concentration of the target chemical species “N₂” is increased in units of 50 PPM. For example, as illustrated in FIG. 4F, under the condition that the pressure in the vacuum state is 200 mTorr, the flow rate of the target chemical species “N₂” is increased by a small amount in units of 50 PPM. In this example, the range of the emission intensity of the monitoring chemical species “CN” when the flow rate of the target chemical species “N₂” is 50 PPM does not overlap the range of the emission intensity of the monitoring chemical species “CN” when the flow rate of the target chemical species “N₂” is 100 PPM. For example, even though the flow rate of the target chemical species “N₂” is changed only slightly, the emission intensity of the monitoring chemical species “CN” is significantly changed.

As described above, the monitoring chemical species may have higher emission intensity than the target chemical species while being strongly correlated with the target chemical species. Accordingly, the vacuum leakage detection device according to the embodiment of the present disclosure may effectively detect vacuum leakage.

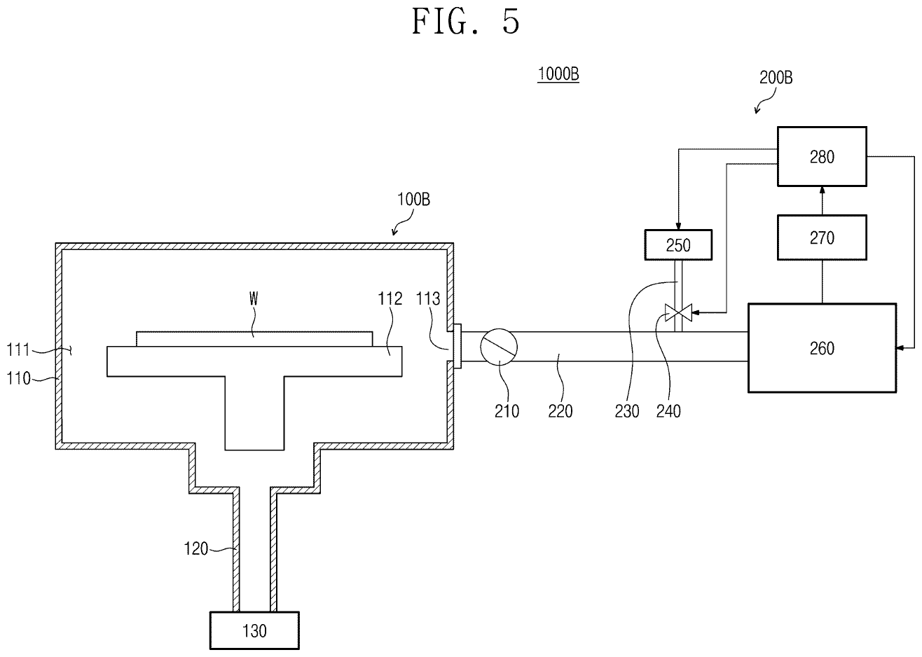

FIG. 5 is a view illustrating a semiconductor manufacturing system according to an example embodiment of the present disclosure. The semiconductor manufacturing system 1000B of FIG. 5 is similar to the semiconductor manufacturing system 1000A of FIG. 1. Therefore, identical or similar components will be assigned with the same reference numerals, and repetitive description will be omitted.

Referring to FIG. 5, the semiconductor manufacturing system 1000B may include a semiconductor manufacturing device 100B and a vacuum leakage detection device 200B. In this example, a sampling inlet 113 may be disposed at one side of a process chamber 110 of the semiconductor manufacturing device 100B, and the vacuum leakage detection device 200B may be connected to the sampling inlet 113. For example, unlike the vacuum leakage detection device 200A of FIG. 1 that is connected to one side of the exhaust pipe 120, the vacuum leakage detection device 200B of FIG. 5 may be connected to one side of the process chamber 110.

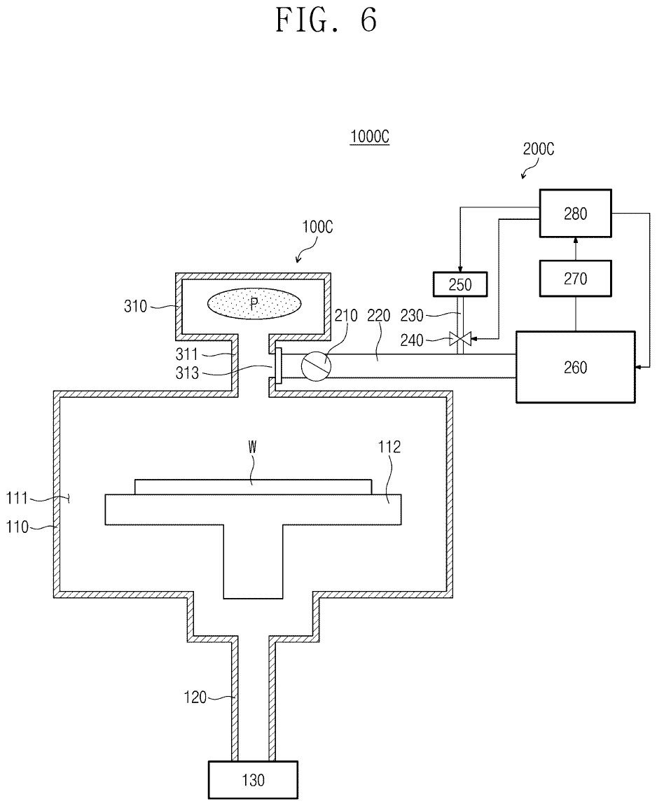

FIG. 6 is a view illustrating a semiconductor manufacturing system according to an embodiment of the present disclosure. The semiconductor manufacturing system 1000C of FIG. 6 is similar to the semiconductor manufacturing systems 1000A and 1000B of FIGS. 1 and 5. Therefore, identical or similar components will be assigned with the same reference numerals, and repetitive description will be omitted.

Referring to FIG. 6, the semiconductor manufacturing system 1000C may include a semiconductor manufacturing device 100C and a vacuum leakage detection device 200C.

The semiconductor manufacturing device 100C may include a remote plasma source 310, a process chamber 110, and a vacuum pump 130.

The remote plasma source 310 may generate plasma P. For example, the remote plasma source 310 may generate plasma using microwave power. However, this is illustrative, and in some embodiments, the remote plasma source 310 may generate plasma through an inductively coupled plasma (ICP) method or a capacitive coupled plasma (CCP) method. A process gas and a control gas may be supplied to the remote plasma source 310. The plasma P may be generated in the remote plasma source 310 as appropriate power is provided under appropriate pressure and temperature conditions.

The semiconductor manufacturing device 100C may perform an etching process, a deposition process, and a cleaning process using the plasma P generated in the remote plasma source 310. For example, the semiconductor manufacturing device 100C may perform a deposition process, such as an ALD process, using radicals generated in the plasma.

A plasma pipe 311 may be disposed between the remote plasma source 310 and the process chamber 110. The plasma pipe 311 may correspond to a passage through which the plasma P generated in the remote plasma source 310 is supplied to the process chamber 110. The plasma pipe 311 may be formed of, for example, a metallic material similar to or the same as that of the process chamber 110.

In an example embodiment, a sampling inlet 313 may be formed in one side surface of the remote plasma source 310, and the vacuum leakage detection device 200C may be connected to the sampling inlet 313 formed in the one side surface of the remote plasma source 310. Accordingly, the vacuum leakage detection device 200C may detect occurrence or non-occurrence of vacuum leakage from the remote plasma source 310 and/or the process chamber 110. However, this is illustrative, and the present disclosure is not limited thereto. In some embodiments, a sampling inlet for connecting the vacuum leakage detection device 200C may be formed in the plasma pipe 311 and a pipe (not illustrated) that supplies the process gas and the control gas to the remote plasma source 310.

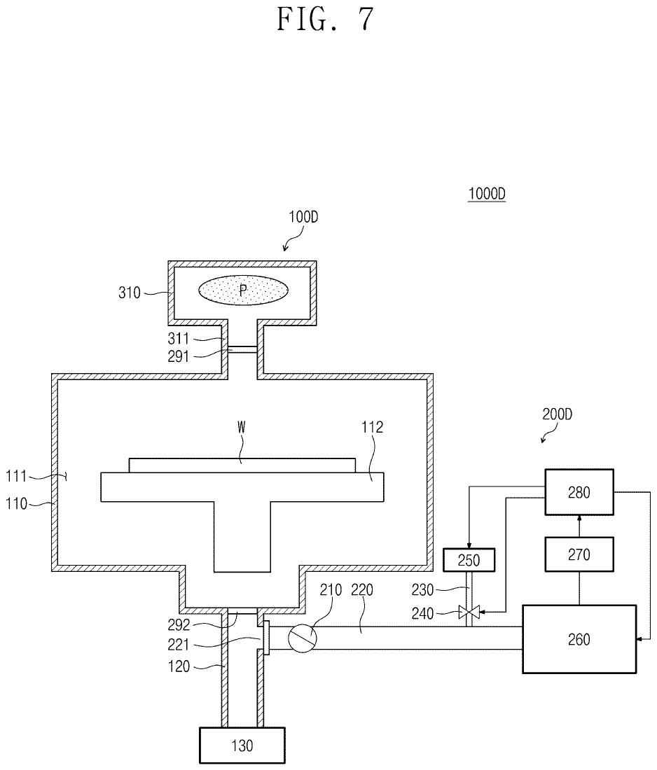

FIG. 7 is a view illustrating a semiconductor manufacturing system according to an embodiment of the present disclosure.

The semiconductor manufacturing system 1000D of FIG. 7 is similar to the semiconductor manufacturing systems 1000A, 1000B, and 1000C of FIGS. 1, 5, and 7. Therefore, identical or similar components will be assigned with the same reference numerals, and repetitive description will be omitted.

Referring to FIG. 7, the semiconductor manufacturing system 1000D may include a semiconductor manufacturing device 100D. A space in the semiconductor manufacturing device 100D may provide a partition check operation for tracking a portion where vacuum leakage occurs.

In an embodiment, the semiconductor manufacturing device 100D may include a first opening/closing device 291 and a second opening/closing device 292. The first opening/closing device 291 may physically isolate a remote plasma source 310 and a process chamber 110 from each other. The second opening/closing device 292 may physically isolate the process chamber 110 and an exhaust pipe 120 from each other. However, this is illustrative, and in some embodiments, only one of the first opening/closing device 291 and the second opening/closing device 292 may be provided. Alternatively, in some embodiments, an additional opening/closing device other than the first opening/closing device 291 and the second opening/closing device 292 may be provided.

In an embodiment of the present disclosure, the semiconductor manufacturing system 1000D may selectively isolate a detection target area. In this example, the semiconductor manufacturing system 1000D may detect whether vacuum leakage occurs in the detection target area, by detecting a change in the emission spectrum of a monitoring chemical species.

Hereinafter, for convenience of description, it is assumed that the remote plasma source 310, the process chamber 110, and the exhaust pipe 120 are detection target areas.

First, occurrence or non-occurrence of vacuum leakage for the entire semiconductor manufacturing device 100D and the amount of leakage may be detected using the present devices, systems and methods. For example, a vacuum leakage detection device 200D may be connected to the semiconductor manufacturing device 100D. Thereafter, occurrence or non-occurrence of vacuum leakage for the entire semiconductor manufacturing device 100D and the amount of leakage may be detected in the state in which both the first opening/closing device 291 and the second opening/closing device 292 are open. If vacuum leakage occurs, the vacuum leakage detection device 200D may store emission spectrum data for the monitoring chemical species.

Thereafter, the vacuum leakage detection device 200D may select the remote plasma source 310 as a detection target area. In this example, the first opening/closing device 291 may be closed, and thus the remote plasma source 310 may be isolated from the process chamber 110.

Thereafter, the vacuum leakage detection device 200D may determine whether vacuum leakage from the remote plasma source 310 occurs, by identifying a change in the emission spectrum for the monitoring chemical species.

In more detail, if vacuum leakage from the remote plasma source 310 occurs, the process chamber 110 and the exhaust pipe 120 may be in a vacuum state as the first opening/closing device 291 is closed. In this example, the emission spectrum for the monitoring chemical species is changed from a defect state to a normal state. In contrast, if vacuum leakage from the remote plasma source 310 does not occur, the process chamber 110 and the exhaust pipe 120 may be in a vacuum leakage state even though the first opening/closing device 291 is closed. In this example, the emission spectrum for the monitoring chemical species is maintained in a defect state. As described above, the vacuum leakage detection device 200D may determine whether vacuum leakage from the remote plasma source 310 occurs, by identifying a change in the emission spectrum for the monitoring chemical species in the state in which the remote plasma source 310 is isolated.

If vacuum leakage from the remote plasma source 310 does not occur, the vacuum leakage detection device 200D may select the exhaust pipe 120 as a detection target area. In this example, the second opening/closing device 292 may be closed, and thus the exhaust pipe 120 may be isolated from the process chamber 110.

Thereafter, the vacuum leakage detection device 200D may determine whether vacuum leakage from the exhaust pipe 120 occurs, by identifying a change in the emission spectrum for the monitoring chemical species.

In more detail, if vacuum leakage from the exhaust pipe 120 occurs, the exhaust pipe 120 may be in a vacuum leakage state even though the second opening/closing device 292 is closed. In this example, the emission spectrum for the monitoring chemical species is maintained in a defect state. In contrast, if vacuum leakage from the exhaust pipe 120 occurs, the exhaust pipe 120 may be in a vacuum state as the second opening/closing device 292 is closed. In this example, the emission spectrum for the monitoring chemical species is changed from a defect state to a normal state. As described above, the vacuum leakage detection device 200D may determine whether vacuum leakage from the exhaust pipe 120 occurs, by identifying a change in the emission spectrum for the monitoring chemical species in the state in which the exhaust pipe 120 is isolated.

If vacuum leakage from the remote plasma source 310 and the exhaust pipe 120 does not occur, the vacuum leakage detection device 200D may determine that vacuum leakage from the process chamber 110 occurs.

In FIG. 7, it has been described that the remote plasma source 310, the process chamber 110, and the exhaust pipe 120 are detection target areas capable of being isolated. However, this is illustrative, and depending on the structure of the semiconductor manufacturing device 100D, various parts may be set as detection target areas capable of being isolated.

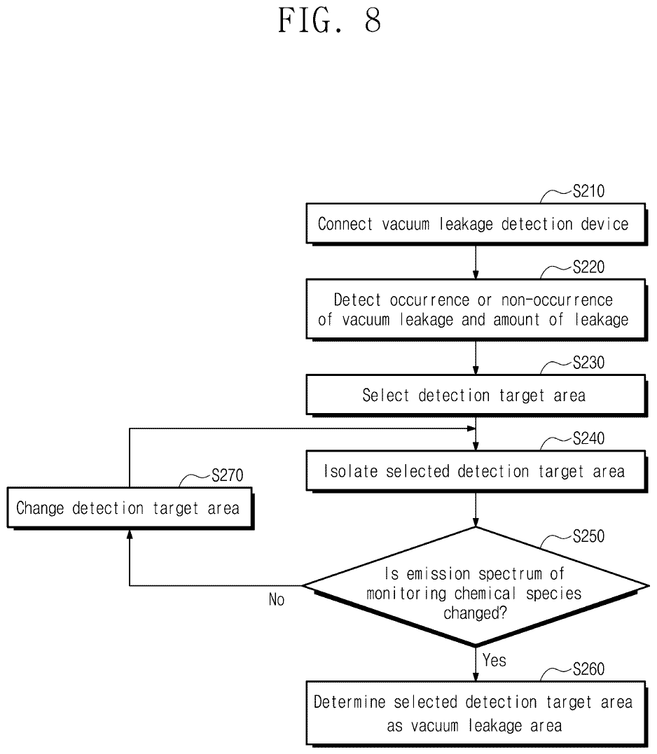

FIG. 8 is a flowchart for explaining an example of operation of the semiconductor manufacturing system and the vacuum leakage detection device of FIG. 7.

In step S210, the vacuum leakage detection device 200D may be connected to the semiconductor manufacturing device 100D.

For example, as illustrated in FIG. 7, the vacuum leakage detection device 200D may be connected to the exhaust pipe 120. However, this is illustrative, and in some embodiments, the semiconductor manufacturing device 100D may have inlets formed in various parts, and the vacuum leakage detection device 200D may be connected to one of the inlets of the semiconductor manufacturing device 100D.

In step S220, the vacuum leakage detection device 200D may detect occurrence or non-occurrence of vacuum leakage and the amount of leakage.

For example, as described with reference to FIG. 2, the vacuum leakage detection device 200D may add an additional chemical species capable of reacting with a target chemical species and may obtain emission spectrum data for the additional chemical species. If vacuum leakage occurs, the vacuum leakage detection device 200D may determine that the corresponding emission spectrum data is defective and may store the corresponding emission spectrum data.

In step S230, a detection target area where occurrence or non-occurrence of vacuum leakage is to be determined may be selected.

For example, an area where occurrence or non-occurrence of vacuum leakage is to be determined may be selected from locations in the semiconductor manufacturing device 100D.

In step S240, the detection target area may be isolated from other areas.

For example, the semiconductor manufacturing device 100D may isolate the detection target area from the other areas by using the first opening/closing device 291 and the second opening/closing device 292.

In step S250, it may be determined whether there is a change in the emission spectrum of a monitoring chemical species.

If vacuum leakage from the isolated detection target area occurs, the emission spectrum of the monitoring chemical species is changed from a defect state to a normal state. In this example, step S260 may be performed. In step S250, the vacuum leakage detection device 200D may determine that vacuum leakage from the selected detection target area occurs and may calculate the leakage amount for the selected detection target area using the correlation between the monitoring chemical species and the target chemical species.

If vacuum leakage from the isolated detection target area occurs, the emission spectrum of the monitoring chemical species is maintained in a defect state. In this example, step S270 may be performed. In step S260, the detection target area may be changed. Thereafter, steps S240 and S250 may be performed again.

The vacuum leakage detection device 200D may determine that vacuum leakage from the selected detection target area occurs and may calculate the leakage amount for the selected detection target area using the correlation between the monitoring chemical species and the target chemical species.

As described above, the space in the semiconductor manufacturing device 100D according to the embodiment of the present disclosure may be divided into a plurality of spaces/locations, and the vacuum leakage detection device 200D may detect occurrence or non-occurrence of vacuum leakage from each space/location.

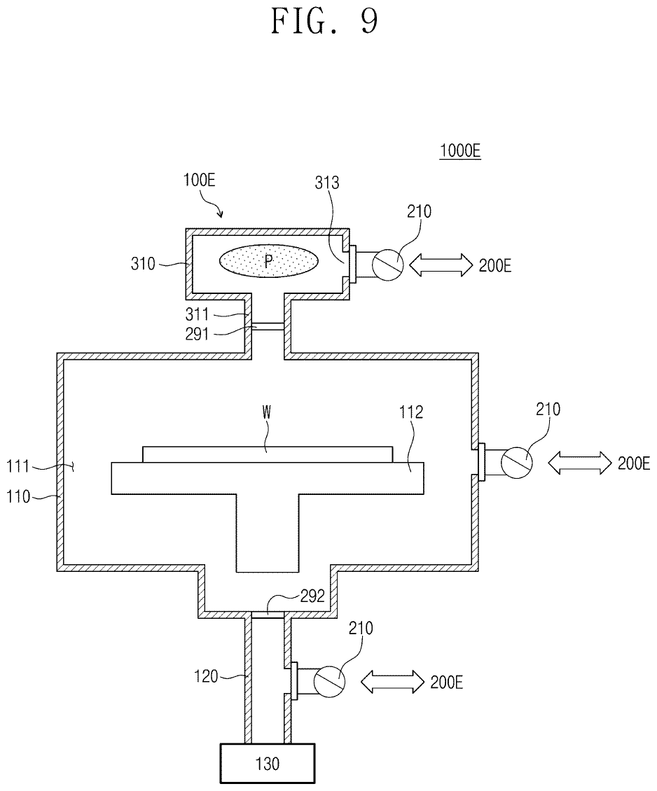

FIG. 9 is a view illustrating a semiconductor manufacturing system according to an embodiment of the present disclosure.

The semiconductor manufacturing system 1000E of FIG. 9 is similar to the semiconductor manufacturing systems 1000A, 1000B, and 1000C of FIGS. 1, 5, 7, and 8. Therefore, identical or similar components will be assigned with the same reference numerals, and repetitive description will be omitted.

Referring to FIG. 9, the semiconductor manufacturing system 1000E may include a semiconductor manufacturing device 100E. A space in the semiconductor manufacturing device 100E may provide a partition check operation for tracking a portion where vacuum leakage occurs.

In an embodiment, the semiconductor manufacturing device 100E may include a first opening/closing device 291 and a second opening/closing device 292. The first opening/closing device 291 may physically isolate a remote plasma source 310 and a process chamber 110 from each other. The second opening/closing device 292 may physically isolate the process chamber 110 and an exhaust pipe 120 from each other.

For example, occurrence or non-occurrence of vacuum leakage from the remote plasma source 310 may be determined. In this example, the first opening/closing device 291 may be closed, and thus the remote plasma source 310 may be isolated from the process chamber 110. A vacuum leakage detection device 200E may be connected to one side surface of the remote plasma source 310 and may detect occurrence or non-occurrence of vacuum leakage from the remote plasma source 310 and the amount of leakage.

For example, occurrence or non-occurrence of vacuum leakage from the process chamber 110 may be determined. In this example, the first opening/closing device 291 and the second opening/closing device 292 may be closed, and the process chamber 110 may be isolated from the remote plasma source 310 and the exhaust pipe 120. The vacuum leakage detection device 200E may be connected to one side surface of the process chamber 110 and may detect occurrence or non-occurrence of vacuum leakage from the process chamber 110 and the amount of leakage.

For example, occurrence or non-occurrence of vacuum leakage from the exhaust pipe 120 may be determined. In this example, the second opening/closing device 292 may be closed, and thus the exhaust pipe 120 may be isolated from the process chamber 110. The vacuum leakage detection device 200E may be connected to one side surface of the exhaust pipe 120 and may detect occurrence or non-occurrence of vacuum leakage from the exhaust pipe 120 and the amount of leakage.

In FIG. 9, it has been described that the semiconductor manufacturing device is divided into three parts (a remote plasma source 310, a process chamber 110, and an exhaust pipe 120). However, this is illustrative, and the present disclosure is not limited thereto. In some embodiments, the semiconductor manufacturing device may be divided into N number of areas, and occurrence or non-occurrence of vacuum leakage and the amount of leakage may be detected for each of the N areas.

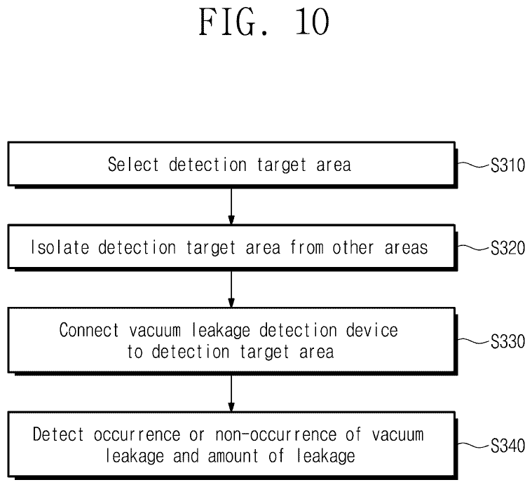

FIG. 10 is a flowchart for explaining an example of operation of the semiconductor manufacturing system and the vacuum leakage detection device of FIG. 9.

In step S310, a detection target area where occurrence or non-occurrence of vacuum leakage is to be determined may be selected.

For example, an area where occurrence or non-occurrence of vacuum leakage is to be determined may be selected from spaces/locations in the semiconductor manufacturing device 100E.

In step S320, the detection target area may be isolated from other areas.

For example, the semiconductor manufacturing device 100E may isolate the detection target area from the other areas by using the first opening/closing device 291 and the second opening/closing device 292.

In step S330, the vacuum leakage detection device 200E may be connected to the detection target area.

In step S340, the vacuum leakage detection device 200E may detect occurrence or non-occurrence of vacuum leakage and the amount of leakage.

For example, as described with reference to FIG. 2, the vacuum leakage detection device 200E may add an additional chemical species capable of reacting with a target chemical species and may obtain emission spectrum data for the additional chemical species. Thereafter, the vacuum leakage detection device 200E may calculate occurrence or non-occurrence of vacuum leakage and the amount of leakage by using the correlation between the additional chemical species and the target chemical species.

As described above, the space in the semiconductor manufacturing device 100E according to the embodiment of the present disclosure may be divided into a plurality of spaces/locations, and the vacuum leakage detection device 200E may detect occurrence or non-occurrence of vacuum leakage from each space/location.

The detection device according to the embodiment of the present disclosure may efficiently detect vacuum leakage from the process chamber.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A vacuum leakage detection device for detecting vacuum leakage from a semiconductor manufacturing device, the vacuum leakage detection device comprising:
a first pipe to introduce a target chemical species from the semiconductor manufacturing device, the first pipe being configured to be connected with the semiconductor manufacturing device;
an additional gas supplier configured to supply an additional gas including an additional chemical species to the first pipe to react with the target chemical species;
a second pipe connecting the additional gas supplier and the first pipe to introduce the additional chemical species to the first pipe;
a flow meter disposed in-line with the second pipe and configured to control a flow rate of the additional chemical species into the first pipe;
a plasma generator connected to the first pipe and configured to convert a monitoring chemical species into a plasma state, the monitoring chemical species being generated by reaction of the target chemical species and the additional chemical species;
a sensor configured to obtain emission spectrum data for the monitoring chemical species from the plasma generator; and
a processor configured to calculate a leakage amount of the target chemical species from the semiconductor manufacturing device, based on emission intensity as determined from the emission spectrum data of the monitoring chemical species.

2. The vacuum leakage detection device of claim 1, wherein the processor adjusts a concentration of the additional chemical species introduced from the additional gas supplier into the first pipe by controlling the flow meter based on the emission spectrum data for the monitoring chemical species.

3. The vacuum leakage detection device of claim 1,
wherein the first pipe is configured to be connected to an exhaust pipe of the semiconductor manufacturing device.

4. The vacuum leakage detection device of claim 1,
wherein the first pipe is configured to be connected a process chamber of the semiconductor manufacturing device.

5. The vacuum leakage detection device of claim 1,
wherein the first pipe is configured to be connected to a remote plasma source of the semiconductor manufacturing device.

6. The vacuum leakage detection device of claim 1, wherein the processor is configured to detect and react to an emission intensity from the emission spectrum data of cyanogen as the monitoring chemical species.

7. The vacuum leakage detection device of claim 1, further comprising:
an isolation valve disposed in-line with the first pipe and configured to attach/detach the first pipe to/from the semiconductor manufacturing device without a break of a vacuum state of a process chamber of the semiconductor manufacturing device.

8. A semiconductor manufacturing system comprising:
a semiconductor manufacturing device; and
a vacuum leakage detection device connected to the semiconductor manufacturing device and configured to detect vacuum leakage from the semiconductor manufacturing device,
wherein the vacuum leakage detection device includes:
a first pipe to introduce a target chemical species from the semiconductor manufacturing device, the first pipe being configured to be connected with the semiconductor manufacturing device;
an additional gas supplier configured to supply an additional gas including an additional chemical species to the first pipe to react with the target chemical species;
a second pipe connecting the additional gas supplier and the first pipe to introduce the additional chemical species to the first pipe;
a flow meter disposed in-line with the second pipe and configured to control a flow rate of the additional chemical species into the first pipe;
a plasma generator connected to the first pipe and configured to convert a monitoring chemical species into a plasma state, the monitoring chemical species being generated by reaction of the target chemical species and the additional chemical species;
a sensor configured to obtain emission spectrum data for the monitoring chemical species from the plasma generator; and
a processor configured to calculate a leakage amount of the target chemical species from the semiconductor manufacturing device, based on emission intensity as determined from the emission spectrum data of the monitoring chemical species.

9. The semiconductor manufacturing system of claim 8, wherein the semiconductor manufacturing device includes:
a remote plasma source configured to generate plasma;
a process chamber connected to the remote plasma source;
a plasma pipe disposed between the process chamber and the remote plasma source and configured to transfer the plasma to the process chamber;
a vacuum pump connected to the process chamber;
an exhaust pipe connected between the process chamber and the vacuum pump;
a first opening/closing device configured to isolate the remote plasma source from the process chamber; and
a second opening/closing device configured to isolate the exhaust pipe from the process chamber.

10. The semiconductor manufacturing system of claim 9, wherein the first pipe of the vacuum leakage detection device is connected to the remote plasma source of the semiconductor manufacturing device in a closed state of the first opening/closing device and detects occurrence or non-occurrence of vacuum leakage from the remote plasma source.

11. The semiconductor manufacturing system of claim 9, wherein the first pipe of the vacuum leakage detection device is connected to the process chamber of the semiconductor manufacturing device in a closed state of the first opening/closing device and the second opening/closing device and detects occurrence or non-occurrence of vacuum leakage from the process chamber.

12. The semiconductor manufacturing system of claim 9, wherein the first pipe of the vacuum leakage detection device is connected to the exhaust pipe of the semiconductor manufacturing device in a closed state of the second opening/closing device and detects occurrence or non-occurrence of vacuum leakage from the exhaust pipe.

13. The semiconductor manufacturing system of claim 9, wherein the first pipe of the vacuum leakage detection device is connected to the exhaust pipe of the semiconductor manufacturing device, and
one of the remote plasma source, the process chamber, and the exhaust pipe is selected as a detection target area by selectively changing the first opening/closing device and the second opening/closing device to a closed state.

14. The semiconductor manufacturing system of claim 8, wherein the processor adjusts a concentration of the additional chemical species introduced from the additional gas supplier into the first pipe by controlling the flow meter based on the emission spectrum data for the monitoring chemical species.

15. The semiconductor manufacturing system of claim 8, wherein the system further includes the target chemical species, the additional chemical species and the monitoring chemical species, and wherein the target chemical species is nitrogen, the additional chemical species is carbon dioxide, and the monitoring chemical species is cyanogen.

16. The semiconductor manufacturing system of claim 8, further comprising:
an isolation valve disposed in-line with the first pipe and configured to attach the first pipe to the semiconductor manufacturing device without a break of a vacuum state of a process chamber of the semiconductor manufacturing device.

17. A method for operating a vacuum leakage detection device, the method comprising:
providing a target chemical species through a first pipe to a plasma generator;
setting an initial concentration of an additional chemical species to react with the target chemical species;
controlling a flow meter disposed in-line with a second pipe through which the additional chemical species is to be transmitted, based on the initial concentration of the additional chemical species;
generating a monitoring chemical species by reacting the target chemical species and the additional chemical species;
exciting the monitoring chemical species into a plasma state within the plasma generator by activating the plasma generator; and
obtaining emission spectrum data for the monitoring chemical species from the plasma generator.

18. The method of claim 17, further comprising:
determining whether a flow rate of an additional gas including the additional chemical species is appropriate, based on the emission spectrum data for the monitoring chemical species.

19. The method of claim 18, further comprising:
calculating a leakage amount of the target chemical species based on a correlation between the monitoring chemical species and the target chemical species when the flow rate of the additional gas is appropriate.

20. The method of claim 17, further comprising:
selecting a detection target area where occurrence or non-occurrence of vacuum leakage is to be determined, from a semiconductor manufacturing device;
isolating the detection target area from other areas of the semiconductor manufacturing device; and
determining occurrence or non-occurrence of vacuum leakage from the detection target area, based on a change in the emission spectrum data for the monitoring chemical species.
